(19) United States
(12) Patent Application Publication
(10) Pub. No.: US 2025/0244672 A1
(43) Pub. Date: Jul. 31, 2025

(54) BAKE STRATEGIES TO ENHANCE LITHOGRAPHIC PERFORMANCE OF METAL-CONTAINING RESIST

(71) Applicant: Lam Research Corporation, Fremont, CA (US)

(72) Inventors: Timothy William WEIDMAN, Sunnyvale, CA (US); Chenghao WU, San Jose, CA (US); Katie Lynn NARDI, San Jose, CA (US); Boris VOLOSSKIY, San Jose, CA (US); Kevin Li GU, Mountain View, CA (US)

(21) Appl. No.: 19/182,430

(22) Filed: Apr. 17, 2025

Related U.S. Application Data
(63) Continuation of application No. 17/596,858, filed on Dec. 20, 2021.
(60) Provisional application No. 62/868,708, filed on Jun. 28, 2019.

(51) Int. Cl. G03F 7/16; G03F 7/004; G03F 7/20

(52) U.S. Cl. CPC G03F 7/168; G03F 7/0043; G03F 7/2004

(57) ABSTRACT

Various embodiments herein relate to methods, apparatus, and systems for baking metal-containing on a semiconductor substrate in the presence of a reactive gas species. For example, the method may include receiving the substrate in a process chamber, the substrate having a photoresist layer thereon, where the photoresist layer includes a metal-containing photoresist material; flowing a reactive gas species from a gas source, through a gas delivery line, into the process chamber, and exposing the substrate to the reactive gas species in the process chamber; and baking the photoresist layer while the substrate is exposed to the reactive gas species.

### INCORPORATION BY REFERENCE

An Application Data Sheet is filed concurrently with this specification as part of the present application. Each application that the present application claims benefit of or priority to as identified in the concurrently filed Application Data Sheet is incorporated by reference herein in their entireties and for all purposes.

### FIELD

This disclosure relates generally to the field of semiconductor processing. In particular aspects, the disclosure is directed to process and apparatus for processing of photoresists in the context of lithographic patterning and film development to form a patterning mask.

### BACKGROUND

As semiconductor fabrication continues to advance, feature sizes continue to shrink and new processing methods are needed. One area where advances are being made is in the context of patterning, for example using photoresist materials that are patterned through exposure to radiation.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Various embodiments herein relate to methods, apparatus, and systems for baking a photoresist layer on a substrate. In one aspect of the disclosed embodiments, a method of baking a photoresist layer on a substrate is provided, the method including: receiving the substrate in a process chamber, the substrate including the photoresist layer thereon, where the photoresist layer includes a metal-containing photoresist material; flowing a reactive gas species from a gas source, through a gas delivery line, into the process chamber, and exposing the substrate to the reactive gas species in the process chamber; and baking the photoresist layer while the substrate is exposed to the reactive gas species.

In various embodiments, the photoresist layer includes an extreme ultraviolet (EUV) photoresist material. In some embodiments, the reactive gas species includes a gas selected from the group consisting of: water, hydrogen, oxygen, ozone, hydrogen peroxide, carbon monoxide, carbon dioxide, ammonia, nitrous oxide, nitric oxide, an alcohol, acetyl acetone, formic acid, oxalyl chloride, pyridine, a carboxylic acid, an amine, and combinations thereof. In some cases, the reactive gas species may include the water. In these or other cases, the reactive gas species may include the hydrogen. In these or other cases, the reactive gas species may include the oxygen. In these or other cases, the reactive gas species may include the ozone. In these or other cases, the reactive gas species may include the hydrogen peroxide. In these or other cases, the reactive gas species may include the carbon monoxide. In these or other cases, the reactive gas species may include the carbon dioxide. In these or other cases, the reactive gas species may include the ammonia. In some such cases, baking the photoresist occurs after the photoresist has been exposed to EUV radiation to pattern the photoresist, and one of the following conditions is satisfied: (i) the process chamber is maintained at atmospheric pressure while baking the photoresist, and the ammonia is provided at a concentration between about 0.001-5% (by volume), or (ii) the process chamber is maintained at sub-atmospheric pressure while baking the photoresist, and the ammonia is provided at a partial pressure between about 1-100 mTorr. In these or other cases, the reactive gas species may include the nitrous oxide and/or the nitric oxide. In these or other cases, the reactive gas species may include the alcohol. In these or other cases, the reactive gas species may include the acetyl acetone. In these or other cases, the reactive gas species may include the formic acid. In these or other cases, the reactive gas species may include the oxalyl chloride. In these or other cases, the reactive gas species may include the carboxylic acid. In these or other cases, the reactive gas species may include the amine. Example amines may include methylamine, dimethylamine, trimethylamine, cthylamine, diethylamine, and/or triethylamine in certain cases. In various embodiments, the reactive gas species may be oxidative. In these or other cases, the reactive gas species may be polar.

In certain implementations, exposing the substrate to the reactive gas species may promote cross-linking within the photoresist layer. In these or other embodiments, exposing the substrate to the reactive gas species may promote removal of low molecular weight species in the photoresist layer. For example, the low molecular weight species may include zero, one, or two metal atoms per molecule. In some embodiments, exposing the substrate to the reactive gas species may oxidize a metal hydride species in the photoresist layer to a metal hydroxide species.

In certain implementations, the method may further include applying vacuum to the process chamber while baking the photoresist layer. In these or other embodiments, the method may further include controlling a concentration of water in the process chamber such that it remains within a target water concentration range while baking the photoresist layer. Similarly, the method may include controlling a concentration of oxygen in the process chamber such that it remains within a target oxygen concentration range while baking the photoresist layer. In some embodiments, the process chamber may be maintained at or below atmospheric pressure while baking the photoresist layer. For example, in some cases the process chamber may be maintained below atmospheric pressure while baking the photoresist layer.

A support on which the substrate is positioned may be temperature controlled while baking the photoresist layer. For instance, in some embodiments the method may further include increasing a temperature of the substrate support on which the substrate is positioned while baking the photoresist layer. In these or other embodiments, the method may further include decreasing a temperature of the substrate support on which the substrate is positioned while baking the photoresist layer. In some cases, the method may include controlling a flow of the reactive species into the process chamber to achieve a target degree of crosslinking. Various different types of heat may be provided. In some embodiments, baking the photoresist layer includes heating the substrate on a hot plate. In some embodiments, baking the photoresist layer includes exposing the substrate to infrared radiation and/or ultraviolet radiation. In some embodiments, baking the photoresist layer may include heating the substrate from above. In these or other embodiments, baking the photoresist layer may include heating the substrate from below.

The methods described herein may be used for different applications. In some cases, the photoresist layer has been applied to the substrate but not yet patterned, and the baking is a post-application bake (PAB). In other cases, the photoresist layer has been applied to the substrate and patterned by partial exposure to EUV radiation resulting in exposed and unexposed portions of the photoresist layer, and the baking is a post-exposure bake (PEB). In these or other embodiments, the reactive gas species may include polar and oxidative molecules. For instance, the reactive gas species may include hydrogen peroxide.

In another aspect of the disclosed embodiments, an apparatus for baking a photoresist layer on a substrate is provided, the apparatus including: a process chamber; an inlet for introducing a reactive gas species to the process chamber; an outlet for removing materials from the process chamber; a substrate support in the process chamber; a heater configured to heat the substrate through conduction, convection, and/or radiation; and a controller having at least one processor, where the at least one processor is configured to control the apparatus to cause any of the methods claimed or otherwise described herein.

These and other aspects are described further below with reference to the drawings.

### BRIEF DESCRIPTION OF THE DRAWINGS

FIG. 1 presents a flow chart describing a lithographic patterning process according to various embodiments.

FIG. 2 presents a simplified view of a processing chamber according to certain embodiments.

### DETAILED DESCRIPTION

Reference is made herein in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

Patterning of thin films in semiconductor processing is often an important step in the fabrication of semiconductors. Patterning involves lithography. In conventional photolithography, such as 193 nm photolithography, patterns are printed onto a photosensitive photoresist film by exposing the photoresist to photons in selective areas defined by a photomask, and thereby causing a chemical reaction in the photoresist and creating chemical contrast that can be leveraged in the development step to remove certain portions of the photoresist to form the pattern. The patterned and developed photoresist film then can be used as an etch mask to transfer the pattern into the underlying films that are composed of metal, oxide, etc.

Advanced technology nodes (as defined by the International Technology Roadmap for Semiconductors) including nodes 22 nm, 16 nm, and beyond, require continuous improvement in lithography resolution. In the 16 nm node, for example, the width of a via or line in a Damascene structure is typically no greater than about 30 nm, which is not possible with simple 193 nm photolithography, or otherwise involves complex multi-patterning schemes.

Extreme ultraviolet (EUV) lithography can extend lithography technology by moving to smaller imaging source wavelengths than would be achievable with conventional photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, as well as ambient-pressure gases, and so EUV scanners operate in a vacuum.

EUV lithography makes use of EUV resists that are patternable using EUV light to form masks for use in etching underlying layers. EUV resists may be polymer-based chemically amplified resists (CARs) produced by liquid-based spin-on techniques. An alternative to CARs are directly photopatternable metal-oxide based EUV photoresist (PR) films. Such PR films may be produced by (wet) spin-on techniques, such as those available from Inpria, Corvallis, OR, and as described, for example, in US Patent Publications US 2017/0102612 and US 2016/0116839, incorporated by reference herein at least for their disclosure of photopatternable metal oxide-containing films, or dry vapor-deposited as described in Application PCT/US19/31618, filed May 9, 2019, and titled METHODS FOR MAKING EUV PATTERNABLE HARD MASKS, the disclosures of which at least relating to the composition and patterning of directly photopatternable metal oxide films to form EUV resist masks is incorporated by reference herein. These directly photopatternable EUV resists may be composed of or contain high-EUV-absorbance metals and their organometallic oxides/hydroxides and other derivatives. Upon EUV exposure, EUV photons as well as secondary electrons generated can induce chemical reactions, such as beta-H elimination reaction in SnOx-based resist (and other metal oxide based resists), and provide chemical functionality to facilitate cross-linking and other changes in the resist film. These chemical changes can then be leveraged in the development step to selectively remove the exposed or unexposed area of the resist film and to create an etch mask for pattern transfer.

It should also be understood that the while present disclosure relates to lithographic patterning techniques and materials exemplified by EUV lithography, it is also applicable to other next generation lithographic techniques. In addition to EUV, which includes the standard 13.5 nm EUV wavelength currently in use and development, the radiation sources most relevant to such lithography are DUV (deep-UV), which generally refers to use of 248 nm or 193 nm excimer laser sources, X-ray, which formally includes EUV at the lower energy range of the X-ray range, as well as e-beam, which can cover a wide energy range. The specific methods may depend on the particular materials and applications used in the semiconductor substrate and ultimate semiconducting device. Thus, the methods described in this application are merely exemplary of the methods and materials that may be used in present technology.

Photolithography processes typically involve one or more bake steps to facilitate the chemical reactions required to produce chemical contrast between exposed and unexposed areas of the photoresist. For high volume manufacturing (HVM), such bake steps are typically performed on tracks where the wafers are baked on a hot-plate at a pre-set temperature under ambient-air or in some cases N₂ flow. More careful control of the bake ambient as well as introduction of an additional reactive gas component in the ambient during these bake steps can help further reduce the dose requirement and/or improve pattern fidelity.

This disclosure describes a new bake strategy that involves careful control of the bake ambient, introduction of reactive gases, and in some cases careful control of the ramping rate of the bake temperature. Such a strategy can be particularly useful for metal oxide based EUV photoresist (PR). Examples of useful reactive gases include water, hydrogen, oxygen, ozone, hydrogen peroxide, carbon monoxide, carbon dioxide, ammonia, nitrous oxide, nitric oxide, methylamine, dimethylamine, alcohols, acetyl acetone, formic acid, oxalyl chloride, carboxylic acids, other amines, substituted forms of any of these materials, etc. The reactive gas is provided in gaseous form, and may be vaporized before delivery to the reaction chamber. Various example gases are further discussed below.

While this disclosure is not limited to any particular theory or mechanism of operation, it is understood that these reactive gas molecules can potentially accelerate cross-linking behavior of the metal oxide based EUV photoresist in the EUV exposed area (the area that remains to form the mask following development of the patterned film in this example) via oxidation, coordination, or acid/base chemistry, while having limited impact on the cross-linking in the unexposed area. Alternatively or in addition, in some cases, the reactive gas molecules may promote removal of volatile species from the metal oxide based EUV photoresist, thereby further increasing the stability of the resist.

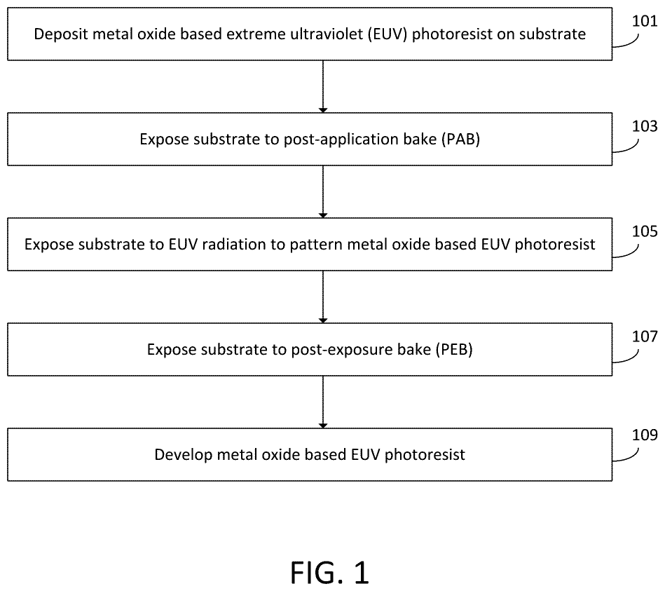

FIG. 1 presents a flow chart according to various embodiments. At operation 101, resist is deposited on the substrate. The substrate on which the resist is deposited typically includes underlying materials that will eventually be etched after the resist is patterned/developed. In various embodiments, the substrate on which the resist is deposited may have an exposed layer of amorphous carbon, spin-on-carbon (SoC), spin-on glass (SoG), silicon oxide, silicon nitride, silicon oxynitride, silicon carbide, silicon oxycarbide, etc. In many cases the exposed layer is an ashable hardmask (AHM). The resist that is deposited in operation 101 is a metal oxide based EUV photoresist. The deposition may occur through wet spin-on techniques or dry vapor-based techniques such as chemical vapor deposition (CVD) and/or atomic layer deposition (ALD), either of which may be driven by thermal energy, plasma energy, or both. Next, at operation 103, the substrate is exposed to heat in a first bake step often referred to as the post-application bake (PAB). At operation 105, the substrate is exposed to EUV radiation to pattern the resist, thereby forming exposed areas and unexposed areas of the resist. Next, at operation 107, the substrate is exposed to heat in a second bake step often referred to as the post-exposure bake (PEB). Then, at operation 109, the resist is developed to selectively remove the unexposed areas. In various embodiments herein, the atmosphere to which the substrate is exposed may be controlled during the PAB of operation 103 and/or during the PEB of operation 107. For instance, the substrate may be exposed to one or more reactive gases during these steps. Each of the bake steps are further discussed below.

### 1. Post-Application Bake (PAB)

The post-application bake is performed after the resist is deposited on the substrate, and before the resist is exposed to EUV radiation for patterning. See operation 103 of FIG. 1. The PAB may be performed to drive off excess solvent (e.g., in cases where the resist is deposited through spin-on methods), drive off other low molecular weight or otherwise volatile species, and promote a desired degree of cross-linking within the resist. These features operate to increase the stability of the resist. For example, by driving off low molecular weight or otherwise volatile species that are unbound or only loosely bound within the resist, the outgassing of metal-containing molecules can be reduced to an acceptable amount (e.g., <1E10 molecules/(cm²*month)). It is advantageous to remove these materials because they could otherwise contaminate downstream processes, equipment, and substrates. The cross-linking achieved during PAB likewise increases the stability of the resist; however, too much cross-linking can lead to increases in line width roughness. As such, cross-linking may be controlled to a desired degree during the PAB.

In various embodiments herein, the substrate may be exposed to a reactive gas during the PAB. The reactive gas may promote removal of low molecular weight or otherwise volatile species. In various embodiments, the low molecular weight species that are removed during the PAB may have zero metal atoms, 1 metal atom, or 2 metal atoms. In some cases, the low molecular weight species that are removed may include dimetal species. Molecules having three or more metal atoms typically have a relatively higher molecular weight and are relatively less volatile, and may substantially remain in the resist during the PAB. In addition to removing low molecular weight species, the reactive gas may promote a desired degree of cross-linking within the resist. As a result of these features, the use of reactive gas during the PAB may help stabilize the resist.

Example processing apparatus and reactive gases are provided below. The substrate may be exposed to any one or more of these reactive gases during the PAB in various embodiments. In a particular example, the substrate may be exposed to a processing atmosphere having a controlled amount of oxygen and/or moisture (e.g., water vapor) along with inert gas during the PAB. In some embodiments, appropriate gas sensors and feedback mechanisms may be used to ensure that the composition of the processing atmosphere is controlled within desired ranges.

In various embodiments, one or more processing condition may be controlled as follows during the PAB. The substrate may be heated to an elevated temperature between about 100-170° C., for example between about 100-130° C. in some cases. The pressure may be maintained between about 0.1-760 Torr, for example between about 0.1-1 Torr in some cases. The substrate may be exposed to the elevated temperature for a duration between about 1-10 minutes, for example between about 2-5 minutes. Inert gases may be flowed into the processing chamber at a rate between about 10-10,000 sccm. In a particular example, the concentration of oxygen (e.g., O₂) in the processing chamber may be controlled during the PAB. In these or other embodiments, the concentration of water (e.g., H₂O vapor) may be controlled during the PAB.

In some embodiments the PAB may be omitted. The PAB may not be needed in cases where the resist is deposited through dry vapor-based techniques, rather than wet spin-on techniques, for example because there is no need to remove excess solvent used to deposit the resist. However, even where the resist is deposited through dry vapor-based techniques, it can be advantageous to perform a PAB to promote a desired degree of crosslinking and to remove low molecular weight or otherwise non-volatile species, which may be a larger concern with dry vapor based deposition techniques than with wet spin-on deposition techniques. In some embodiments, the PAB may be a conventional PAB. In other words, the PAB may occur without exposing the substrate to a reactive gas species and/or in a non-controlled atmosphere. In such embodiments, the substrate may be exposed to a reactive gas species during the post-exposure bake, as discussed further below.

### 2. Post-Exposure Bake (PEB)

The post-exposure bake is performed after the resist is exposed to EUV radiation for patterning, and before the resist is developed to remove unexposed portions of the resist. See operation 107 of FIG. 1. The PEB may be performed for several purposes, for example: 1) to drive complete evaporation of the organic fragments that are generated during EUV exposure; 2) to oxidize the metal hydride species (the other product from the beta-H elimination reaction during EUV exposure) into metal hydroxide; and 3) to facilitate the cross-linking between neighboring-OH groups and form a cross-linked metal oxide network.

The bake temperature is carefully selected to achieve optimal EUV lithographic performance. Too low a PEB temperature would lead to incomplete removal of organic fragments as well as insufficient cross-linking, and consequently less chemical contrast for development at a given dose. Too high a PEB temperature would also have detrimental impacts, including severe oxidation and film shrinkage in the unexposed area (the area that is removed by development of the patterned film to form the mask in this example), as well as, undesired interdiffusion at the interface between PR and underlayer (UL; typically a spin-on carbon material), both of which will contribute to loss of chemical contrasts and an increase in defect density due to insoluble scum. Having the bake temperature and bake time as the only knobs, the tunability and process window is often very limited.

Careful control on the bake ambient and introduction of reactive gas species during the PEB process, as described herein, provides an additional chemistry knob to fine-tune the cross-linking process. For example, having polar and oxidative molecules like H₂O₂ present during the bake step can facilitate the oxidation of the metal hydride in the exposed area, because the exposed area tends to be more polar than unexposed area due to the loss of alkyl groups and formation of hydride/hydroxide components. Other gases such as those described below in the Reactive Gases section may also change the kinetics of hydride oxidation and hydroxide cross-linking reaction via oxidation, acid/base chemistry, coordination chemistry, and the combination of them. The reactive gas(es) may be provided in a controlled atmosphere, for example using any of the apparatus described in the Bake Apparatus section below. The reactive gases may be provided along with non-reactive gases such as N₂, Ar, He, Ne, Kr, Xe, etc. In some cases, air or clean dry air may be provided in the atmosphere during the PEB.

The ability to tune the kinetics of cross-linking behavior in metal oxide based EUV photoresist materials provides a wider process window that allows for further optimization of lithographic performance by minimizing interdiffusion and other relevant defect formation mechanisms. For instance, if reactive gases can effectively bring down the bake temperature requirement, then the interdiffusion concerns at the PR/UL interface can be alleviated, which will be beneficial for defect reduction.

In certain embodiments, one or more processing condition may be controlled as follows during the PEB. The substrate may be heated to an elevated temperature between about 100-250° C., for example between about 120-200° C. in some cases. The pressure may be maintained between about 0.1-760 Torr, for example between about 0.1-1 Torr in some cases. The substrate may be exposed to the elevated temperature for a duration between about 1-10 minutes, for example between about 2-5 minutes. Inert gases may be flowed into the processing chamber at a rate between about 10-10,000 sccm. In a particular example, the concentration of oxygen (e.g., O₂) in the processing chamber may be controlled during the PEB. In these or other embodiments, the concentration of water (e.g., H₂O vapor) may be controlled during the PEB.

In a particular embodiment, the substrate may be exposed to ammonia during the PEB. In some cases, ammonia may be the only reactive gas present during the PEB, while in other cases one or more additional reactive gas may be provided along with the ammonia. In some embodiments, the ammonia may be provided at a concentration between about 0.001-5.0% (by volume), in some cases between about 0.001-0.5% (by volume) at atmospheric pressure, or at a partial pressure between about 1-100 mTorr, in some cases between about 1-10 mTorr when the process chamber is under vacuum. The duration of the PEB (and/or the duration of substrate exposure to ammonia during the PEB) may be between about 5 seconds and about 10 minutes, in some cases between about 5 seconds and 1 minute. After the substrate is exposed to the ammonia, the process chamber may be purged with inert gas. In various embodiments, the duration of the inert gas purge may be as long or longer than the duration over which the substrate is exposed to ammonia. These steps may promote the alkaline catalysis of M-OH condensation/cross-linking, which causes formation of relatively higher molecular weight, less volatile species, resulting in a more stable photoresist film, as discussed above. These steps may also harden and densify areas of the film that have been exposed to EUV radiation (or other types of lithographic patterning radiation), and may enable these effects at lower bake temperatures than would otherwise be required to achieve the same film properties. In some embodiments, these same reaction conditions may be used during a PAB. In some cases, these same reaction conditions may be used during PAB and/or PEB with an alternative or additional reactive gas described herein, including but not limited to other volatile amines such as methylamine, dimethylamine, trimethylamine, ethylamine, diethylamine, triethylamine, pyridine, etc.

In some embodiments, the PEB may be a conventional PEB. In other words, the PEB may be performed without providing any reactive gases to the substrate and/or in a non-controlled atmosphere. In such cases, one or more reactive gas may be provided to the substrate during the PAB.

### 3. Reactive Gases

In various embodiments herein, a substrate may be exposed to one or more reactive gases during a photoresist bake operation. The reactive gas may promote a desired degree of cross-linking, promote removal of low molecular weight or otherwise volatile species, and/or stabilize the photoresist, as described above.

A number of different reactive gases may be used. Examples of useful reactive gases include water (H₂O), hydrogen (H₂), oxygen (O₂), ozone (O₃), hydrogen peroxide (H₂O₂), carbon monoxide (CO), carbon dioxide (CO₂), ammonia (NH₃), nitrous oxide (N₂O), nitric oxide (NO), methylamine (CH₃NH₂), dimethylamine ((CH₃)₂NH), trimethylamine (N(CH₃)₃), ethylamine (CH₃CH₂NH₂), diethylamine ((CH₃CH₂)₂NH), triethylamine (N(CH₂CH₃)₃), alcohols (CₙH₂ₙ₊₁OH, including but not limited to methanol, ethanol, propanol, and butanol), acetyl acetone (CH₃COCH₂COCH₃), formic acid (HCOOH), oxalyl chloride ((COCl)₂), carboxylic acids (CₙH₂ₙ₊₁COOH), and other small molecule amines (NR¹R²R³, where each of R¹, R², and R³ is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof), etc. Substituted forms of these reactive gases may also be used. In some cases, the substrate may be exposed to two or more reactive gases during a photoresist bake operation.

The reactive gas may interact with the photoresist via oxidation, coordination, or acid/base chemistry. In some cases where the reactive gas is delivered during a PEB operation, the reactive gas may preferentially interact with the photoresist in areas that were exposed to EUV radiation. This preferential interaction may arise due to the chemical changes that occur during EUV exposure, for example the loss of alkyl groups within the photoresist.

Following exposure of the substrate to reactive gas during PAB and/or PEB, the chamber in which the substrate is processed may be evacuated and/or purged, for example with inert gas. In some cases, the duration of the inert gas purge may be at least as long as the duration over which the substrate is exposed to the reactive gas.

### 4. Temperature Ramping

In some embodiments, the rate at which the substrate temperature changes may be controlled during a bake step. Rapid heating and cooling can be problematic in some cases. By controlling the rate at which the substrate temperature increases or decreases, the problems associated with rapid heating and cooling can be avoided. Further, the rate at which the bake temperature is ramped up and/or down may be controlled to fine tune the cross-linking behavior in the resist.

### 5. Bake Apparatus

The bake operations described herein may occur on various different types of processing apparatus. In some cases, the processing apparatus may have a closed chamber that is sealed from the ambient environment. In other cases, the processing apparatus may have an open chamber that is not sealed from the ambient. In certain cases where an open chamber is used, the substrates may be processed on a track, which may operate continuously or non-continuously. Generally, closed chambers provide better control over the processing atmosphere, and provide additional safety with respect to potentially hazardous reactive chemicals. However, open chambers may be preferred in some cases, for example where high volume manufacturing and non-hazardous chemistry are used.

The chamber may be equipped with one or more inlets for providing a desired processing atmosphere. The desired processing atmosphere may include one or more reactive gas as described above. As such, the inlet may be fluidically connected with a reactive gas source. The reactive gas may flow from the reactive gas source, through a gas delivery line, through the inlet, and into the chamber. In cases where the reactive gas is liquid at relevant temperatures, it may be stored as liquid and then vaporized before delivery to the gas delivery line/inlet/chamber. In addition, air and/or inert gas (e.g., N₂, Ar, He, Ne, Kr, Xe, etc.) may be provided to the processing atmosphere in certain implementations. These may likewise flow from a gas source, through a gas delivery line, through an inlet, and into the chamber. In some cases, the processing atmosphere may be air-free.

The chamber may also be equipped with one or more outlets for removing materials from the chamber. The outlet may be fluidically connected with a vacuum source to allow for active removal of gaseous species from the chamber. Vacuum-connected outlets may be used in both closed chambers and open chambers. When used in a closed chamber, a vacuum-connected outlet may enable processing at sub-atmospheric pressures. In cases where the processing chamber is an open chamber that is not sealed from the ambient, the outlet may be any path through which gas can passively escape from the chamber.

As mentioned above, in certain embodiments the atmosphere within the chamber may be controlled during a bake step. In some cases, a concentration of a reactive gas (e.g., oxygen and/or water and/or any of the other reactive gases described herein) may be actively controlled during a bake step. In addition to the inlets and outlets mentioned above, the chamber may be further equipped with sensors (e.g., a residual gas analyzer, a Fourier-transform infrared spectroscopy sensor, etc.) to monitor the composition of the atmosphere in the chamber. These sensors may be used to provide feedback for actively controlling the composition of the bake atmosphere.

In order to bake the photoresist, the chamber is equipped with one or more heating element configured to heat the substrate. The heating element(s) may heat the substrate from above and/or from below. The heating element(s) may heat the front side of the substrate (e.g., where semiconductor devices/structures are being formed) and/or the back side of the substrate. Various different types of heating elements may be used, either alone or in combination with one another. Example heating elements may include heated substrate supports (e.g., pedestals, chucks, etc.) and radiation sources such as infrared lamps and/or ultraviolet lamps.

In some embodiments, the chamber may be equipped with one or more cooling element configured to cool the substrate. For example, the substrate support may be configured to cool the substrate. In one embodiment, the substrate support may include cooling channels through which a heat exchange fluid flows to thereby cool the substrate. Other heat exchange hardware may be used as desired for a particular application. The cooling element may be particularly useful for controlling the rate at which the substrate cools after a baking operation.

The chamber may also be equipped with temperature sensors for monitoring the temperature of the substrate and/or substrate support during a baking operation. In one example, the chamber includes a pyrometer for measuring the temperature of the substrate surface during baking. Temperature measurements from the pyrometer or other temperature sensor may be used as feedback to actively control the temperature of the substrate during baking.

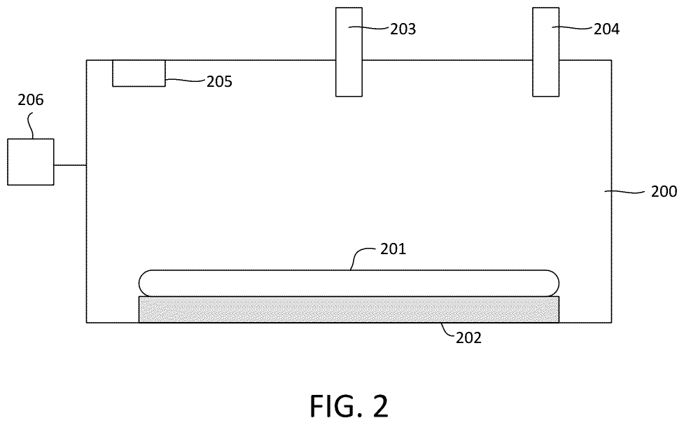

FIG. 2 presents a simplified view of a processing chamber 200 according to one embodiment. In this example, the processing chamber 200 is a closed chamber having a controllable atmosphere. The substrate 201 may be positioned on substrate support 202, which may also heat and/or cool the substrate. Alternative or additional heating and cooling elements may be provided in some cases. Processing gases enter the processing chamber 200 through inlet 203. Materials are removed from the processing chamber 200 through outlet 204, which may be connected to a vacuum source (not shown). Operation of the processing chamber 200 may be controlled by a controller 206, which is further discussed below. Further, a sensor 205 may be provided, for example to monitor temperature and/or the composition of the atmosphere in the processing chamber 200. Readings from sensor 205 may be used by controller 206 in an active feedback loop.

The chamber in which baking takes place may be configured in a number of ways. In some embodiments, the chamber is the same chamber used to deposit the photoresist, and/or the same chamber used to expose the photoresist to EUV radiation, and/or the same chamber used to develop the photoresist. In some embodiments, the chamber is a dedicated bake chamber that is not used for other processes such as deposition, etching, EUV exposure, or photoresist development. The chamber may be a standalone chamber, or it may be integrated into a larger processing tool such as the deposition tool used to deposit the photoresist, the EUV exposure tool used to expose the photoresist to EUV radiation, and/or the development tool used to develop the photoresist. The chamber used for baking may be combined with any one or more of these tools, as desired for a particular application.

The chamber may also be equipped with a controller. In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Bake strategies to enhance EUV-lithographic performance of metal-containing EUV resist are disclosed.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the disclosure.

What is claimed is:

1. A method for increasing chemical contrast between exposed and unexposed areas of a metal-containing photoresist, the method comprising:
contacting the metal-containing photoresist with a reactive gas in a process chamber, wherein the reactive gas comprises an alcohol, a carboxylic acid, an amine, or combinations thereof, wherein the reactive gas is configured to remove low molecular weight species or volatile species to increase chemical contrast between exposed and unexposed areas of the metal-containing photoresist for dry development.

2. The method of claim 1, wherein the reactive gas comprises an alcohol.

3. The method of claim 1, wherein the reactive gas comprises a carboxylic acid.

4. The method of claim 1, wherein the reactive gas comprises an amine.

5. The method of claim 4, wherein the reactive gas comprises methylamine, dimethylamine, trimethylamine, ethylamine, diethylamine, triethylamine, pyridine, or combinations thereof.

6. The method of claim 1, wherein contacting the metal-containing photoresist with the reactive gas occurs at a temperature between about 100° C. and about 250° C.

7. The method of claim 1, wherein contacting the metal-containing photoresist with the reactive gas occurs prior to development.

8. The method of claim 1, wherein the metal-containing photoresist comprises a photopatterned metal oxide EUV photoresist.

9. The method of claim 8, wherein the photopatterned metal oxide EUV photoresist comprises tin oxide.

10. The method of claim 1, wherein the reactive gas is delivered with an inert gas.

11. The method of claim 1, further comprising:
dry developing the metal-containing photoresist after contacting the metal-containing photoresist with the reactive gas.

12. The method of claim 1, wherein the dry development selectively removes the unexposed areas relative to the exposed areas of the metal-containing photoresist to form a resist mask.

13. The method of claim 1, wherein the reactive gas is delivered with water.
